(19) United States
(12) Patent Application Publication
(10) Pub. No.: US 2024/0255856 A1
(43) Pub. Date: Aug. 1, 2024

(54) OPTICAL COMPONENT GROUP, IN PARTICULAR FOR USE IN AN ILLUMINATION DEVICE OF A MICROLITHOGRAPHIC PROJECTION EXPOSURE APPARATUS

(71) Applicant: Carl Zeiss SMT GmbH, Oberkochen (DE)

(72) Inventor: Michael Patra, Oberkochen (DE)

(21) Appl. No.: 18/612,175

(22) Filed: Mar. 21, 2024

Related U.S. Application Data
(63) Continuation of application No. PCT/EP2022/073980, filed on Aug. 29, 2022.

(30) Foreign Application Priority Data
Sep. 21, 2021 (DE) 10 2021 210 491.6

(51) Int. Cl. G03F 7/00

(52) U.S. Cl. CPC G03F 7/70175; G03F 7/702; G03F 7/70075

(57) ABSTRACT

An optical component group, in particular for use in an illumination device of a microlithographic projection exposure apparatus, includes a first reflective component having a first reflection layer system, and a second reflective component having a second reflection layer system. The first reflective component and the second reflective component correspond in terms of the geometry of their optically effective surface. The spectral reflection profiles (r₁ₛ(λ), r₁ₚ(λ)) of the first reflection layer system differ from the corresponding spectral reflection profiles (r₂ₛ(λ), r₂ₚ(λ)) of the second reflection layer system for a given wavelength interval and a given angle of incidence of incident electromagnetic radiation. The spectral reflection profiles of the first reflection layer system describe the respective wavelength dependence of the reflectivity in the case of s-polarized and in the case of p-polarized radiation.

### CROSS REFERENCE TO RELATED APPLICATIONS

This is a Continuation of International Application PCT/EP2022/073980 which has an international filing date of Aug. 29, 2022, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2021 210 491.6 filed on Sep. 21, 2021.

### FIELD OF THE INVENTION

The invention relates to an optical component group, in particular for use in an illumination device of a microlithographic projection exposure apparatus.

### BACKGROUND

Microlithography is used for producing microstructured components, such as for example integrated circuits or LCDs. The microlithography process is conducted in a so-called projection exposure apparatus, which comprises an illumination device and a projection lens. The image of a mask (=reticle) illuminated with the illumination device is projected with the projection lens onto a substrate (e.g., a silicon wafer) that is coated with a light-sensitive layer (photoresist) and arranged in the image plane of the projection lens, in order to transfer the mask structure onto the light-sensitive coating of the substrate.

In projection lenses designed for the extreme ultraviolet (EUV) range, i.e., at wavelengths of, e.g., approximately 13 nm or approximately 7 nm, mirrors are used as optical components for the imaging process because there are no suitable light-transmissive refractive materials available.

During the operation of a projection exposure apparatus there is a need to set specific polarization distributions in the pupil plane and/or in the reticle in a targeted manner in the illumination device for the purpose of optimizing the imaging contrast and also to be able to carry out a change in the polarization distribution during the operation of the projection exposure apparatus. Thus, the use of s-polarized radiation may be advantageous for the purposes of obtaining the highest possible image contrast especially in the case of a projection exposure apparatus for imaging certain structures when the so-called vector effect in the case of relatively large values of the numerical aperture (NA) is taken into account.

However, scenarios where the use of unpolarized radiation rather than an operation with polarized radiation is advantageous also occur in practice during the operation of a projection exposure apparatus. By way of example, this may be the case even for high values of the numerical aperture (NA) if the structures to be imaged within the scope of the lithography process are not linear structures or structures that otherwise define a preferred orientation but structures without a preferred operation (e.g., contact holes). In the latter case, the use of linearly polarized radiation not only fails to yield an advantage but may even be found to be disadvantageous as a consequence of an induced unwanted asymmetry.

Further relevant circumstances are given by the fact that the initial production of unpolarized radiation by the utilized EUV source (e.g., a plasma source), as is conventional, is accompanied by a loss of radiant flux as a matter of principle—specifically as a consequence of the required output coupling of the respective unwanted polarization component—when polarized radiation is provided, which in turn impairs the performance of the projection exposure apparatus.

Consequently, if the aforementioned aspects are taken into account, there is also a need in practice to be able to switch between a mode of operation with polarized radiation and a mode of operation with unpolarized radiation, depending on the operating scenario of the projection exposure apparatus—and in particular depending on the structures to be respectively imaged.

However, the implementation of such a switchover is made more difficult in a projection exposure apparatus designed for operation in EUV by virtue of the fact that, on the one hand, the beam geometry applicable in respect of the beam entry into the illumination device or the beam exit from the illumination device should be maintained from practical points of view while, on the other, no suitable transmissive polarization-optical components such as beam splitters are available in the relevant EUV wavelength range. However, the polarization manipulation on the basis of a reflection below the Brewster angle, as is available in the EUV range, is accompanied by the introduction of one or more additional beam deflections and hence in turn by a significant light loss if an unchanging beam geometry is ensured at the same time.

With respect to the prior art, reference is made, purely by way of example, to DE 10 2008 002 749 A1, DE 10 2018 207 410 A1 and the publication by M. Y. Tan et al.: “Design of transmission multilayer polarizer for soft X-ray using a merit function”, OPTICS EXPRESS Vol. 17, No. 4 (2009), pp. 2586-2599.

### SUMMARY

Against the aforementioned background, it is an object of the present invention to provide an optical component group, in particular for use in an illumination device of a microlithographic projection exposure apparatus, which facilitates a flexible switchover without transmission losses between an operation with polarized radiation and an operation with unpolarized radiation.

This and other objects are achieved according to the features described and claimed herein.

An optical component group according to the invention, in particular for use in an illumination device of a microlithographic projection exposure apparatus, comprises
a first reflective component having a first reflection layer system; and
a second reflective component having a second reflection layer system;
wherein the first reflective component and the second reflective component correspond in terms of the geometry of their optically effective surface; and
wherein the spectral reflection profiles (r₁ₛ(λ), r₁ₚ(λ)) of the first reflection layer system differ from the corresponding spectral reflection profiles (r₂ₛ(λ), r₂ₚ(λ)) of the second reflection layer system for a given wavelength interval and a given angle of incidence of incident electromagnetic radiation, the spectral reflection profiles of the first reflection layer system describing the respective wavelength dependence of the reflectivity in the case of s-polarized and in the case of p-polarized radiation.

In particular, the invention is based on the concept of realizing a flexible switchover between a polarized mode of operation and an unpolarized mode of operation in an EUV illumination device, depending on the application scenario and depending on structures to be imaged in the lithography process in each case, which switchover avoids additional beam deflections, by virtue of exchanging a reflective component situated in the optical beam path of the illumination device for another reflective component with an identical surface geometry but with a different reflection layer system.

Within the meaning of the present application, an illumination device is understood to mean an optical system which illuminates a reticle with a defined spatial and angle distribution by virtue of the radiation of a real or virtual light source being suitably reshaped. In particular, the EUV illumination device according to the invention can receive the radiation of a plasma (i.e., a real light source) via a collector. In further embodiments, the EUV illumination device can also receive the radiation from an intermediate focus (i.e., a virtual light source).

According to the invention, the provision of two different, interchangeable reflective components which, as explained below, differ in terms of their spectral reflection profiles for s- and p-polarized radiation but otherwise correspond to one another in respect of their surface geometry has the consequence that the overall geometry of the beam path within the illumination device remains unchanged even after an exchange of one component for the other component implemented for switching between polarized and unpolarized operation (i.e., a change between a polarising and a non-polarising illumination device) and hence that no additional beam deflections, which are accompanied by an unwanted light loss, are required.

In this case, the invention is based in particular on the insight obtained by the inventor on the basis of comprehensive simulations that the spectral reflection profiles which are respectively applicable to s- and p-polarized radiation and which are provided by the respective reflection layer systems of the reflective components that are exchanged according to the invention can be shifted in a targeted manner by way of a suitable adaptation (e.g., thickness scaling of the individual layers forming the layer stack of the reflection layer system) relative to the relevant “transmission interval” of the entire optical system (i.e., in particular, the subsequent optical component of the illumination device in the beam path).

This targeted adjustment or shift of the spectral reflection profiles applicable to the s- and p-polarized radiation can in turn be implemented, in particular, in such a way that, for the reflective component used in the “polarized operation” of the illumination device or projection exposure apparatus, the respective maximum reflectivity values of the spectral reflection profile applicable to s-polarized radiation but not the respective maximum reflectivity values of the spectral reflection profile applicable to p-polarized radiation are located within the said transmission interval of the optical system. By contrast, the targeted adjustment or shift of the spectral reflection profiles applicable to the s- and p-polarized radiation can be implemented for the reflective component used in the “unpolarized operation” of the illumination device or projection exposure apparatus, in such a way that the maximum reflectivity values of both spectral reflection profiles (i.e., both the spectral reflection profile for p-polarized radiation and the spectral reflection profile for s-polarized radiation) are located within said transmission range.

According to an embodiment, a wavelength λ₀ exists as mean wavelength in a given wavelength interval [(λ₀−Δλ₀/2), (λ₀+Δλ₀/2)] of width Δλ₀ such that the first reflection layer system satisfies the following conditions:

$$( {λ}_{0} - {Δλ}_{0} / 2 ) \geq {λ}_{1 sl} , ( {λ}_{0} + {Δλ}_{0} / 2 ) \leq {λ}_{1 sr} \\ and \\ ( {λ}_{0} - {Δλ}_{0} / 2 ) \leq {λ}_{1 pl} or ( {λ}_{0} + {Δλ}_{0} / 2 ) \geq {λ}_{1 pr} ,$$

where, in the reflection profiles (r₁ₛ(λ), r₁ₚ(λ)) of the first reflection layer system, λ₁ₛₗ and λ₁ₚₗ denote the shortest wavelengths and λ₁ₛᵣ and λ₁ₚᵣ denote the longest wavelengths for which in each case s- and p-polarized radiation, respectively, is reflected with a reflectivity of at least 50% of the maximum reflectivity.

According to an embodiment, a wavelength λ₀ exists as mean wavelength in a given wavelength interval [(λ₀−Δλ₀/2), (λ₀+Δλ₀/2)] of width Δλ₀ such that the second reflection layer system satisfies the following conditions:

$$( {λ}_{0} - {Δλ}_{0} / 2 ) \geq {λ}_{2 sl} , ( {λ}_{0} + {Δλ}_{0} / 2 ) \leq {λ}_{2 sr} \\ and \\ ( {λ}_{0} - {Δλ}_{0} / 2 ) \geq {λ}_{2 pl} , ( {λ}_{0} + {Δλ}_{0} / 2 ) \leq {λ}_{2 pr}$$

where, in the reflection profiles (r₂ₛ(λ), r₂ₚ(λ)) of the second reflection layer system, λ₂ₛₗ and λ₂ₚₗ denote the shortest wavelengths and λ₂ₛᵣ and λ₂ₚᵣ denote the longest wavelengths for which in each case s- and p-polarized radiation, respectively, is reflected with a reflectivity of at least 50% of the maximum reflectivity.

Advantageously, both reflection layer systems may have a common interval [(λ₀−Δλ₀/2), (λ₀+Δλ₀/2)] such that the aforementioned inequality conditions are satisfied.

According to an embodiment, a wavelength λ₀ therefore exists as mean wavelength in a given wavelength interval [(λ₀−Δλ₀/2), (λ₀+Δλ₀/2)] of width Δλ₀ such that the first reflection layer system satisfies the following conditions:

$$( {λ}_{0} - {Δλ}_{0} / 2 ) \geq {λ}_{1 sl} , ( {λ}_{0} + {Δλ}_{0} / 2 ) \leq {λ}_{1 sr} \\ and \\ ( {λ}_{0} - {Δλ}_{0} / 2 ) \leq {λ}_{1 pl} or ( {λ}_{0} + {Δλ}_{0} / 2 ) \geq {λ}_{1 pr} ,$$

the second reflection layer system satisfies the following conditions:

$$( {λ}_{0} - {Δλ}_{0} / 2 ) \geq {λ}_{2 sl} , ( {λ}_{0} + {Δλ}_{0} / 2 ) \leq {λ}_{2 sr} \\ and \\ ( {λ}_{0} - {Δλ}_{0} / 2 ) \geq {λ}_{2 pl} , ( {λ}_{0} + {Δλ}_{0} / 2 ) \leq {λ}_{2 pr}$$

where, in the reflection profiles (r₁ₛ(λ), r₁ₚ(λ)) of the first reflection layer system and (r₂ₛ(λ), r₂ₚ(λ)) of the second reflection layer system, λ₁ₛₗ, λ₁ₚₗ, λ₂ₛₗ and λ₂ₚₗ denote the respective shortest wavelengths and λ₁ₛᵣ, λ₁ₚᵣ, λ₂ₛᵣ and λ₂ₚᵣ denote the respective longest wavelengths for which in each case s- and p-polarized radiation, respectively, is reflected with a reflectivity of at least 50% of the maximum reflectivity.

The achievable width of a reflection profile of an individual mirror is given by λ₁ₛᵣ−λ₁ₛₗ or λ₂ₛᵣ−λ₂ₛₗ. These two values typically differ only a little, and so the mean value Δλ=((λ₁ₛᵣ−λ₁ₛₗ)−(λ₂ₛᵣ−λ₂ₛₗ))/2 only differs slightly from the two individual widths. The width Δλ₀ of the used region and the width Δ\tilde{λ} are typically not independent because the former is based on multiple reflections at a mirroring surface. Typically, the following applies: 0.25Δ\tilde{λ}Δλ₀≤0.4Δ\tilde{λ}.

According to an embodiment, the degree of polarization for the first reflection layer system, defined as the ratio of the reflectivities for s- and p-polarized radiation integrated over the wavelength interval [(λ₀−Δλ₀/2), (λ₀+Δλ₀/2)], is greater than the degree of polarization for the second reflection layer system by a factor of at least 1.5.

According to an embodiment, the optical component group, for s-polarized radiation in an interval [symbol] =[(λ₁ₛᵣ−λ₁ₛₗ)+(λ₂ₛᵣ−λ₂ₛₗ)]/2, has a reflectivity of at least 50% of the maximum transmissivity of the EUV illumination device, where Δλ₀ lies between [symbol] and [symbol] . This criterion is based on the thought that the overall system may typically have a number of reflections, for example ranging from 4 to 9, with the width of the transmission range falling approximately with the square root of the number of reflections.

In embodiments of the invention, both the first and the second reflective component can be a facet mirror, in particular a pupil facet mirror having a plurality of pupil facets or a field facet mirror having a plurality of field facets. In further embodiments, both the first reflective component and the second reflective component can also comprise at least one mirror facet of a facet mirror, in particular of a pupil facet mirror or a field facet mirror.

In further embodiments, both the first and the second reflective component can be a collector mirror.

In further embodiments, both the first and the second reflective component can also comprise at least one micromirror of a specular reflector.

According to an embodiment, the first reflective component and the second reflective component are designed for an operating wavelength of less than 30 nm, in particular less than 15 nm.

Further refinements of the invention can be gathered from the description and the dependent claims.

The invention is explained in greater detail below on the basis of exemplary embodiments illustrated in the accompanying figures.

### BRIEF DESCRIPTION OF THE DRAWINGS

In the figures:

FIGS. 1A-1D show diagrams for explaining different values of the reflectivity for s- and p-polarization, which are obtainable by varying the layer parameters of a reflection layer systems (FIG. 1A: single point; FIG. 1B: first varied material combination for the layers; FIG. 1C: second varied material combination for the layers; FIG. 1D: union of FIG. 1B and FIG. 1C combinations);

FIG. 2 shows a typical wavelength-dependent profile of the intensity corresponding to an exemplary transmission interval of an optical system;

FIGS. 3A and 3B show the wavelength-dependent profiles of the reflectivity for two different reflection layer systems, in each case for both s- and p-polarization;

FIGS. 4A and 4B show the respective wavelength-dependent profiles of the reflectivity for two different reflection layer systems over a greater wavelength range, while simultaneously highlighting an exemplary transmission interval for explaining a concept underlying the invention;

FIG. 5 shows a diagram for explaining terminology used in the present application;

FIGS. 6A-6F show diagrams which show layer thicknesses of periodic layer systems for exemplary angles of incidence, wherein, for the entire range of rₛ, the layers with minimum and maximum rₚ are represented in each case: FIGS. 6A-6C: MoSi 35°; FIGS. 6D-6F: RuSi 60°; FIGS. 6A and 6D: reflectivity rₚ of p-polarized radiation; FIGS. 6B and 6E: individual layer thickness d; FIGS. 6C and 6F: period thickness d₁+d₂;

FIGS. 7A-7H show diagrams in which regions in the rₛ−rₚ diagram obtainable for exemplary periodic or aperiodic layer stacks are represented as a function of various angles of incidence, namely 20°, 25°, 30°, 35°, 55°, 60°, 65°, and 70°, respectively;

FIG. 8 shows a schematic and much simplified representation of the structure, possible in principle, of an illumination device;

FIG. 9 shows a schematic illustration for explaining an exemplary realization of the invention in a pupil facet mirror;

FIG. 10 shows a schematic illustration for explaining a further possible realization of the invention in segments of a pupil facet mirror;

FIG. 11 shows a schematic illustration for explaining a further possible realization in individual pupils of a pupil facet mirror;

FIGS. 12A and 2B show schematic illustrations for explaining a further possible realization of the invention in a field facet mirror, wherein FIG. 12A shows field facets and FIG. 12B shows an exchange apparatus; and

FIG. 13 shows a schematic representation of a fundamentally possible structure of a projection exposure apparatus designed for operation in the EUV.

### DETAILED DESCRIPTION

What is common to the embodiments of the invention described below is the basic concept of providing reflective optical components with differing spectral reflection profiles such that, for a given wavelength interval, one of the two components is suitable for a polarized mode of operation and the other of the two components is suitable for an unpolarized mode of operation. In this case, the aforementioned wavelength interval can be a transmission interval of the respective optical system (e.g., the illumination device of a microlithographic projection exposure apparatus) in particular, for which the reflective optical components according to the invention are destined and which is typically determined by the reflection profile of the remaining optical components present in the optical system (in particular, the downstream optical components in relation to the optical beam path).

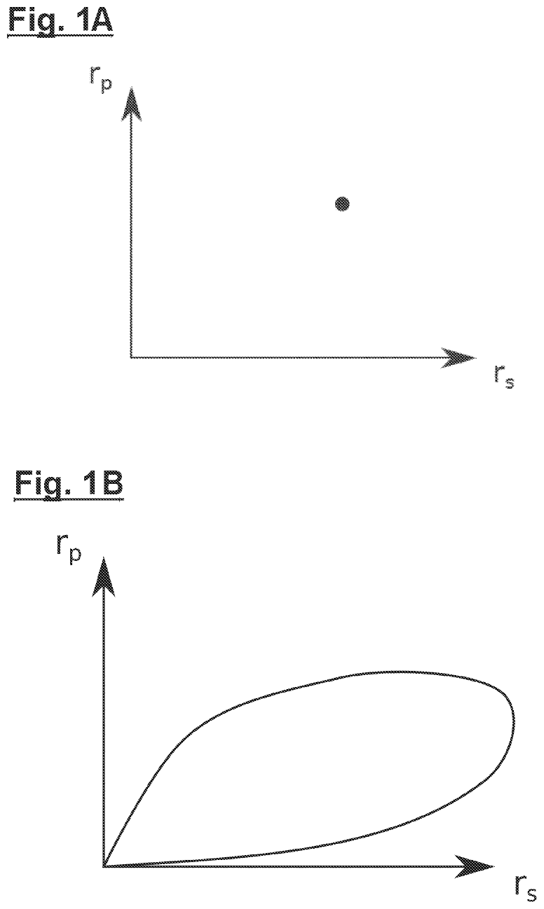

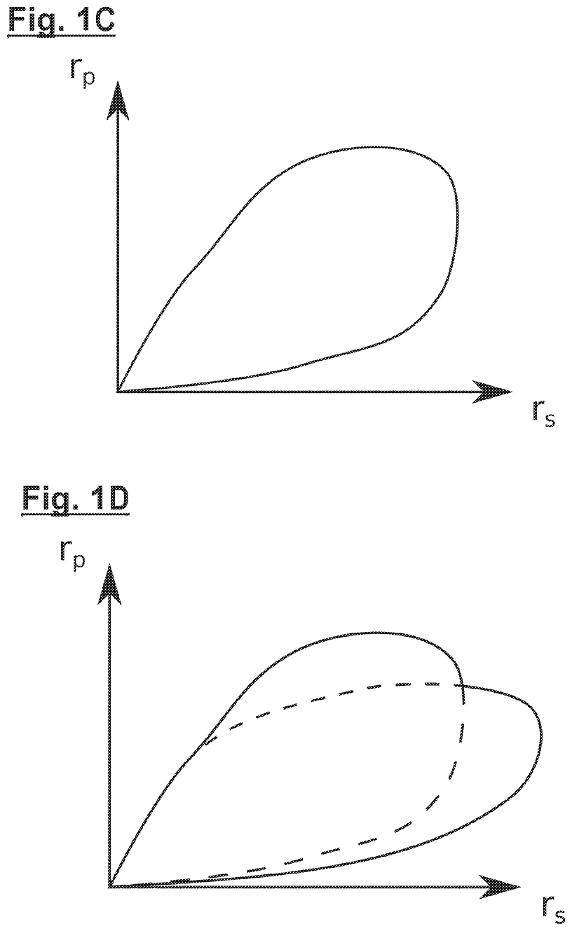

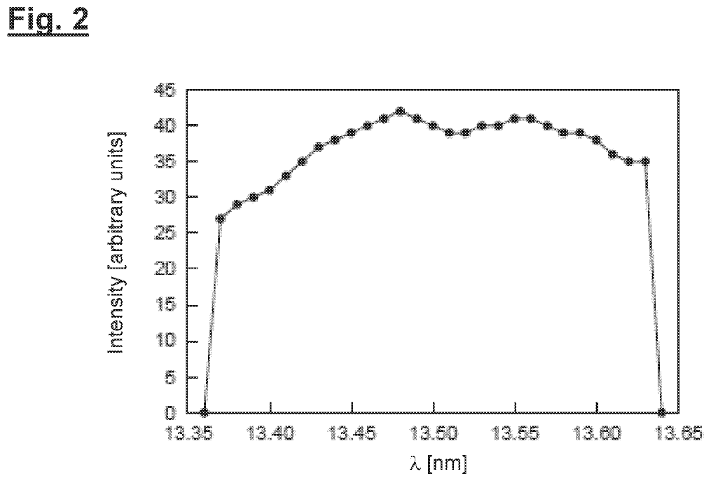

Below, the principle underlying the aforementioned targeted adjustment of the respective reflection layer systems of the reflective optical components according to the invention for the polarized and unpolarized operation, respectively, is initially explained with reference to the diagrams in FIGS. 1-5.

In principle, a given reflection layer system for a given angle of incidence and a given wavelength spectrum of the electromagnetic radiation comprises a certain value rₛ for the reflectivity of s-polarized radiation and a certain value rₚ for the reflectivity of p-polarized radiation. Consequently, according to FIG. 1A, the reflection layer system can be represented as a single point in the rₛ−rₚ diagram.

For given materials of the individual layers within the reflection layer system, the values for rₛ and rₚ are, in turn, dependent on the respective layer thicknesses, and so reflection layer systems with different value pairs (rₛ, rₚ) can be provided by varying these layer thicknesses. As a result, the provision of a multiplicity of corresponding reflection layer systems with different value pairs (rₛ, rₚ) in each case allows coverage of a certain region in the rₛ−rₚ diagram, for example in accordance with FIG. 1B. The specific design of this “obtainable region” in the rₛ−rₚ diagram can in turn be varied by varying the material combinations of the individual layers within the reflection layer system, for the purposes of which FIG. 1C shows an exemplary further possible shape of an obtainable region in the rₛ−rₚ diagram.

Accordingly, a corresponding union of the relevant obtainable regions arises according to FIG. 1D if, over the multiplicity of provided reflection layer systems, corresponding different material combinations of the individual layers are admitted or are present in this multiplicity.

Hence, in principle, the suitable selection of a defined point in the rₛ−rₚ diagram, which in turn corresponds to a uniquely defined layer structure, can be made depending on the intended use or mode of operation and the correspondingly produced reflective optical component can be exchanged where necessary following the simulation of a multiplicity of reflection layer systems or reflective optical components formed thereby. Once again, depending on use scenario, this selection can alternatively be made either to maximize the total reflectance provided by the reflection layer system or to provide a certain degree of polarization (corresponding to a ratio of the reflectivities respectively obtained for s-polarized radiation and p-polarized radiation).

What should be observed in this context is that the ultimately practice-oriented or preferred value pairs (rₛ, rₚ) are located on the respective edge of the obtainable regions, for example according to FIGS. 1B-1D. These circumstances can be traced back to the fact that a point in the rₛ−rₚ diagram situated within the region enclosed by said edge is therefore generally not preferred because it is possible in each case to readily find a point located directly on the edge of said region or a corresponding value pair (rₛ, rₚ) which either has a higher reflectivity overall for the same degree of polarization or which yields a higher degree of polarization for the same reflectivity.

The reflection layer systems used according to the invention can be both periodic and aperiodic layer systems. To provide different spectral reflection profiles both for s-polarized radiation and for p-polarized radiation, the corresponding layer designs are now suitably varied, with the consequence that the wavelength-dependent profile of the respective reflectivities rₛ and rₚ in the relevant transmission interval ultimately has the respective suitable shape for the polarized or unpolarized operation.

FIG. 2 initially shows the typical shape of the spectral radiant flux of an EUV radiation source. The curve has been cut off outside of the wavelength range which in fact also reaches the image plane or wafer plane in the optical system or in the illumination device when the respective spectral reflection profiles of the remaining optical components are taken into account. Since the spectral transmission profile of the optical system or the illumination device typically only approaches zero asymptotically, the two cut-off wavelengths can only be specified approximately in each case.

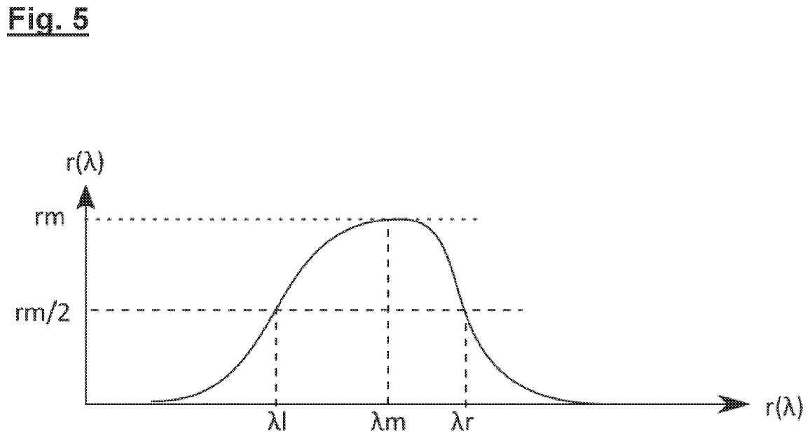

FIG. 5 shows a diagram of a spectral reflection profile r(λ). Here, the maximum reflectivity rₘ occurs at the wavelength λₘ. The shortest wavelength for which radiation is reflected with a reflectivity of at least 50% of the maximum reflectivity is denoted by λₗ. The longest wavelength for which radiation is reflected with a reflectivity of at least 50% of the maximum reflectivity (corresponding to a reflectivity of rₘ/2) is denoted by λᵣ.

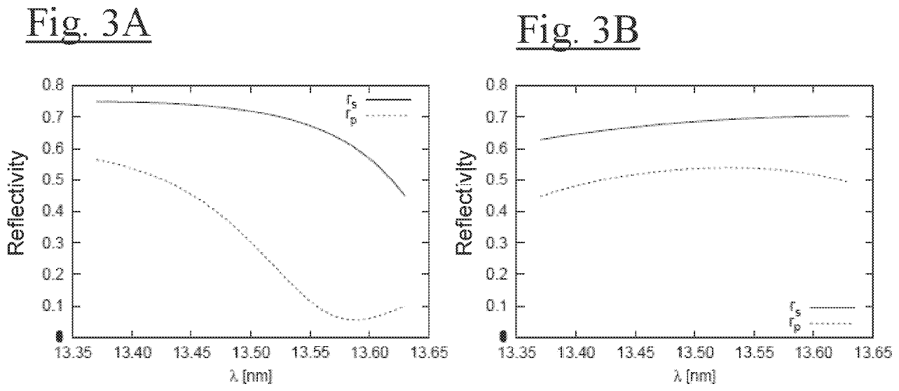

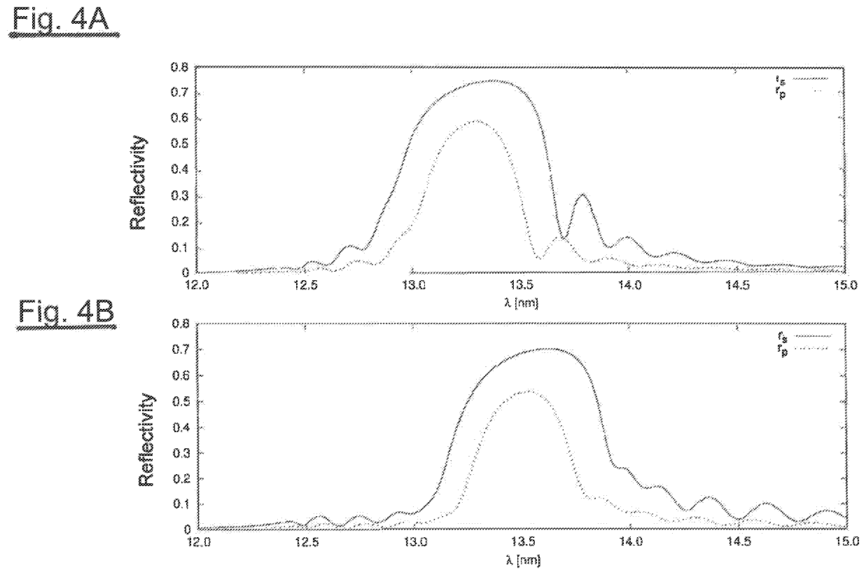

FIGS. 3A-3B now show the respective wavelength-dependent curve of the reflectivity for s-polarization and p-polarization for two exemplary reflection layer systems (aperiodic Mo—Si layer systems in this example). In this case, the relevant multiple layer designs are chosen from a multiplicity of simulated layer designs such that the reflectivity rₚ obtained for p-polarized radiation is minimal for the reflection layer system according to FIG. 3A and maximal for the reflection layer system according to FIG. 3B. The qualitatively different curve of the wavelength-dependent reflectivity, readily identifiable from a comparison of FIG. 3A with FIG. 3B, now becomes evident in terms of its practical relevance according to FIGS. 4A-4B during the respective consideration over a relatively large wavelength range.

As is evident from FIGS. 4A-4B, the peaks of the reflectivity respectively obtained for s-polarization and for p-polarization have different widths, with, according to expectations, the peak in the wavelength-dependent profile of the reflectivity having the greater width for s-polarization in comparison with the peak for p-polarization. What is now achieved with the two aforementioned “extreme” layer designs in respect of the reflectivity rₚ applicable to p-polarization and by exploiting these circumstances is that both peaks (i.e., for s-polarization and for p-polarization) are located within the transmission interval for the reflection layer system according to FIG. 4B, whereas the maximum reflectivity values for s-polarization but not for p-polarization are located within the transmission interval for the reflection layer system according to FIG. 4A (for p-polarization, the falling slope of the corresponding peak of the reflectivity curve instead is situated within the transmission interval according to FIG. 4A).

As a consequence, the reflection layer system according to FIG. 4A has in comparison with that according to FIG. 4B a substantially stronger polarizing effect on the incident electromagnetic radiation. Expressed differently, the reflection layer system according to FIG. 4A is suitable for the mode of operation with polarized radiation and the reflection layer system according to FIG. 4B is suitable for the mode of operation with unpolarized radiation.

The realization of the above-described concept according to the invention in reflection layer systems in the form of aperiodic multiple layer systems now allows the influencing of the two parameters of width and position of the respective peak in the wavelength-dependent reflectivity profile independently of one another by changing the layer design. The corresponding values for s-polarization and p-polarization are correlated for a given layer design, and so width and position of the peaks for s-polarization and p-polarization cannot be chosen completely independently of one another. However, as already explained on the basis of FIGS. 4A-4B, this is not necessary either. By contrast, when realizing the invention with reflection layer systems in the form of periodic layer systems with an alternating periodic sequence of a given number of two different layer materials (“bilayer”), it is substantially only the position of the peak that can be chosen freely, while the width of the peak can only be influenced to a limited extent.

Tables 1-4 represent aperiodic layer designs in exemplary fashion, to be precise for systems made of molybdenum silicon (MoSi) or ruthenium silicon (RuSi). For fixed rₛ=0.7, the tables in each case specify the layer designs that have a maximum and minimum rₚ, respectively.

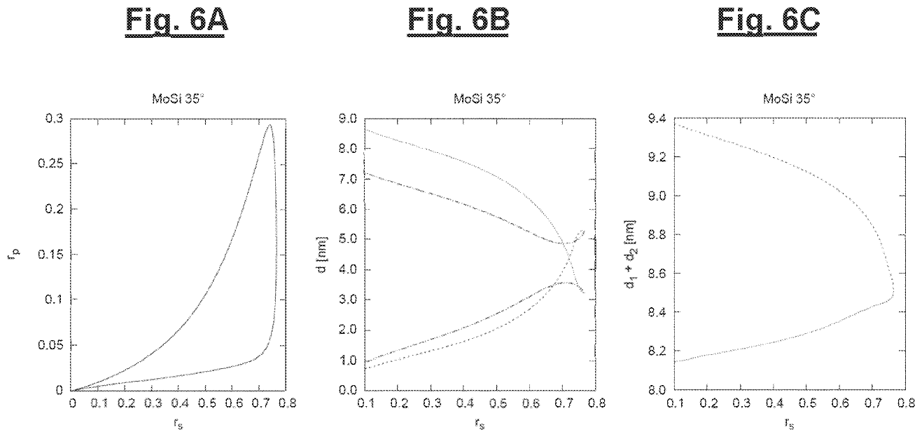

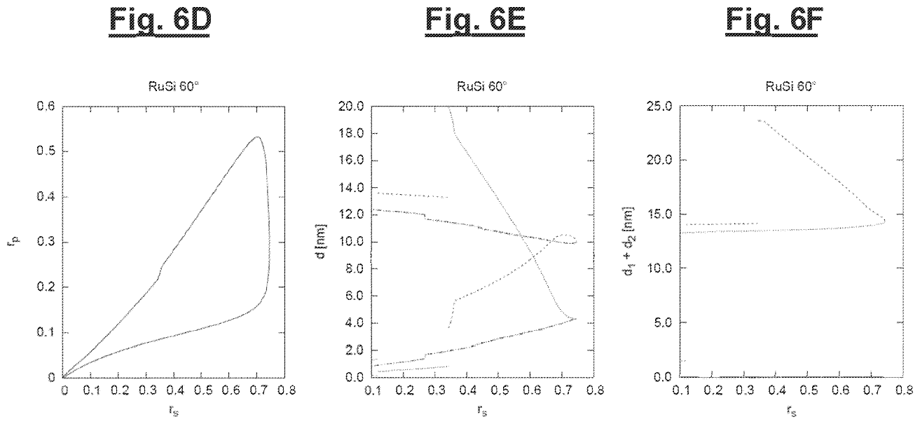

For exemplary angles of incidence (35° and 60°, FIGS. 6A-6F depict the layer thicknesses of periodic layer systems. In this case, the layers with minimum and maximum rₚ are respectively depicted for the entire range of rₛ. In this case, the layers with minimum and maximum rₚ are respectively depicted for the entire range of rₛ. FIGS. 6A and 6D each show the extremally achievable values of rₚ. FIGS. 6B and 6E each show the individual layer thicknesses: The thickness of silicon for maximum rₚ is represented by long dashes. The thickness of molybdenum or ruthenium for maximum rₚ is represented by short dashes. The thickness of silicon for minimum rₚ is represented by a dash-dotted line. The thickness of molybdenum or ruthenium for minimum rₚ is represented by a line with a dash followed by two dots. FIGS. 6C and 6F show the respective period thickness, that is to say the sum of the two individual thicknesses (molybdenum and silicon or ruthenium and silicon).

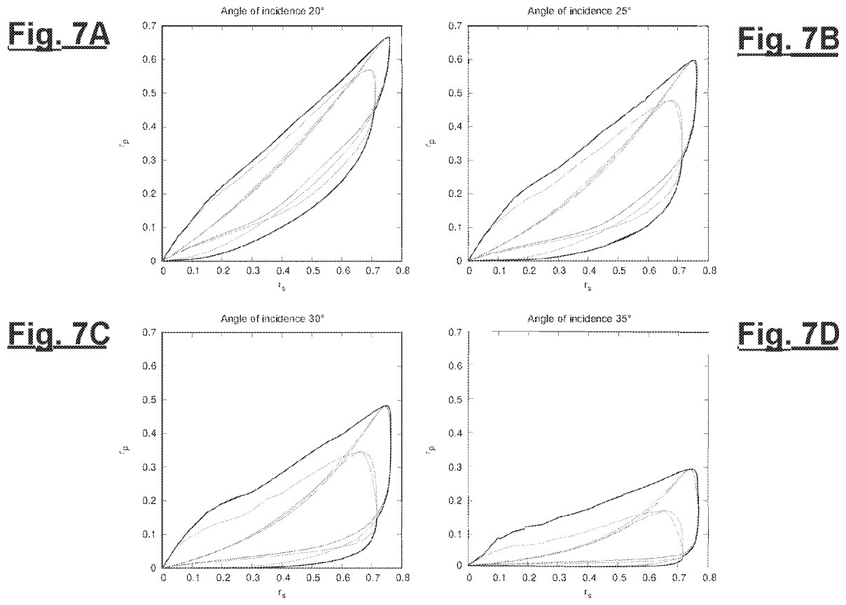

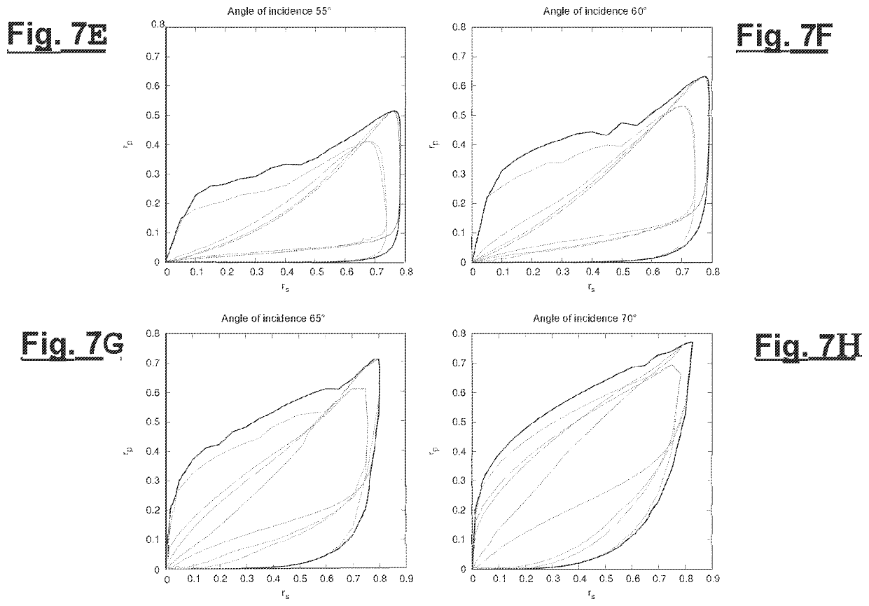

FIGS. 7A-7H show the range in the rₛ−rₚ diagram achievable for MoSi or RuSi by periodic or aperiodic layer stacks, as a function of the angle of incidence. The two components that can be exchanged for one another need not correspond in respect of the material combination (MoSi or RuSi) and/or in respect of the structure (periodic or aperiodic sequence). Especially for angles that are sufficiently different from 0° and the Brewster angle of approximately 45°, the available selection range in the rₛ−rₚ diagram is surprisingly large.

TABLE 1
(RuSi; 60° angle of incidence; rₛ = 0.7; rₚ minimal
The silicon layer of layer 1 is located directly on the substrate.
The ruthenium layer of layer 50 forms the incidence surface
for the EUV used radiation.)

| | | | | |
|---|---|---|---|---|
| 1 | d_{Si} = | 14.0000 nm | d_{Ru} = | 2.3451 nm |
| 2 | d_{Si} = | 11.6620 nm | d_{Ru} = | 0.0000 nm |
| 3 | d_{Si} = | 0.0000 nm | d_{Ru} = | 14.0000 nm |
| 4 | d_{Si} = | 13.9930 nm | d_{Ru} = | 14.0000 nm |
| 5 | d_{Si} = | 0.0000 nm | d_{Ru} = | 14.0000 nm |
| 6 | d_{Si} = | 14.0000 nm | d_{Ru} = | 0.0000 nm |
| 7 | d_{Si} = | 14.0000 nm | d_{Ru} = | 14.0000 nm |
| 8 | d_{Si} = | 0.0000 nm | d_{Ru} = | 14.0000 nm |
| 9 | d_{Si} = | 0.0000 nm | d_{Ru} = | 14.0000 nm |
| 10 | d_{Si} = | 0.0000 nm | d_{Ru} = | 0.0000 nm |
| 11 | d_{Si} = | 14.0000 nm | d_{Ru} = | 14.0000 nm |
| 12 | d_{Si} = | 14.0000 nm | d_{Ru} = | 14.0000 nm |
| 13 | d_{Si} = | 0.0000 nm | d_{Ru} = | 14.0000 nm |
| 14 | d_{Si} = | 14.0000 nm | d_{Ru} = | 0.0000 nm |
| 15 | d_{Si} = | 0.0000 nm | d_{Ru} = | 7.1140 nm |
| 16 | d_{Si} = | 14.0000 nm | d_{Ru} = | 14.0000 nm |
| 17 | d_{Si} = | 14.0000 nm | d_{Ru} = | 0.0000 nm |
| 18 | d_{Si} = | 0.0000 nm | d_{Ru} = | 6.0973 nm |
| 19 | d_{Si} = | 8.5758 nm | d_{Ru} = | 13.5046 nm |
| 20 | d_{Si} = | 0.4454 nm | d_{Ru} = | 11.4563 nm |
| 21 | d_{Si} = | 7.0244 nm | d_{Ru} = | 12.3895 nm |
| 22 | d_{Si} = | 13.9996 nm | d_{Ru} = | 10.4081 nm |
| 23 | d_{Si} = | 3.4224 nm | d_{Ru} = | 12.4434 nm |
| 24 | d_{Si} = | 13.9985 nm | d_{Ru} = | 13.9998 nm |
| 25 | d_{Si} = | 14.0000 nm | d_{Ru} = | 13.9996 nm |
| 26 | d_{Si} = | 4.9534 nm | d_{Ru} = | 13.9966 nm |
| 27 | d_{Si} = | 0.0000 nm | d_{Ru} = | 13.9966 nm |
| 28 | d_{Si} = | 3.8489 nm | d_{Ru} = | 12.8972 nm |
| 29 | d_{Si} = | 0.0000 nm | d_{Ru} = | 13.9958 nm |
| 30 | d_{Si} = | 14.0000 nm | d_{Ru} = | 14.0000 nm |
| 31 | d_{Si} = | 14.0000 nm | d_{Ru} = | 0.0000 nm |
| 32 | d_{Si} = | 9.6313 nm | d_{Ru} = | 1.7682 nm |
| 33 | d_{Si} = | 11.4665 nm | d_{Ru} = | 5.4774 nm |
| 34 | d_{Si} = | 10.1439 nm | d_{Ru} = | 6.3766 nm |
| 35 | d_{Si} = | 9.7245 nm | d_{Ru} = | 6.6627 nm |
| 36 | d_{Si} = | 9.6146 nm | d_{Ru} = | 6.6180 nm |
| 37 | d_{Si} = | 9.6285 nm | d_{Ru} = | 6.4776 nm |
| 38 | d_{Si} = | 9.6654 nm | d_{Ru} = | 6.2996 nm |
| 39 | d_{Si} = | 9.6951 nm | d_{Ru} = | 6.1137 nm |
| 40 | d_{Si} = | 9.7058 nm | d_{Ru} = | 5.9241 nm |
| 41 | d_{Si} = | 9.6964 nm | d_{Ru} = | 5.7233 nm |
| 42 | d_{Si} = | 9.6632 nm | d_{Ru} = | 5.5086 nm |
| 43 | d_{Si} = | 9.6117 nm | d_{Ru} = | 5.2655 nm |
| 44 | d_{Si} = | 9.5779 nm | d_{Ru} = | 4.8707 nm |
| 45 | d_{Si} = | 9.7328 nm | d_{Ru} = | 4.2078 nm |
| 46 | d_{Si} = | 10.0269 nm | d_{Ru} = | 3.6662 nm |
| 47 | d_{Si} = | 10.2061 nm | d_{Ru} = | 3.4160 nm |
| 48 | d_{Si} = | 10.2024 nm | d_{Ru} = | 3.4533 nm |
| 49 | d_{Si} = | 10.0420 nm | d_{Ru} = | 3.9104 nm |
| 50 | d_{Si} = | 9.8148 nm | d_{Ru} = | 4.2305 nm |

TABLE 2
(RuSi; 60° angle of incidence; rₛ = 0.7; rₚ maximal
The silicon layer of layer 1 is located directly on the substrate.
The ruthenium layer of layer 50 forms the incidence surface
for the EUV used radiation.)

| | | | | |
|---|---|---|---|---|
| 1 | d_{Si} = | 0.0000 nm | d_{Ru} = | 6.8950 nm |
| 2 | d_{Si} = | 8.7943 nm | d_{Ru} = | 0.0000 nm |
| 3 | d_{Si} = | 0.0000 nm | d_{Ru} = | 0.0000 nm |
| 4 | d_{Si} = | 14.0000 nm | d_{Ru} = | 11.1499 nm |
| 5 | d_{Si} = | 0.0000 nm | d_{Ru} = | 14.0000 nm |
| 6 | d_{Si} = | 14.0000 nm | d_{Ru} = | 0.0000 nm |
| 7 | d_{Si} = | 14.0000 nm | d_{Ru} = | 14.0000 nm |
| 8 | d_{Si} = | 7.7458 nm | d_{Ru} = | 12.7017 nm |
| 9 | d_{Si} = | 5.4784 nm | d_{Ru} = | 9.9048 nm |
| 10 | d_{Si} = | 11.8243 nm | d_{Ru} = | 9.2929 nm |
| 11 | d_{Si} = | 5.8627 nm | d_{Ru} = | 10.5026 nm |
| 12 | d_{Si} = | 10.1953 nm | d_{Ru} = | 10.0703 nm |
| 13 | d_{Si} = | 5.3878 nm | d_{Ru} = | 10.7100 nm |
| 14 | d_{Si} = | 11.6359 nm | d_{Ru} = | 9.1818 nm |
| 15 | d_{Si} = | 5.2900 nm | d_{Ru} = | 0.0247 nm |
| 16 | d_{Si} = | 0.0904 nm | d_{Ru} = | 0.0927 nm |
| 17 | d_{Si} = | 0.4027 nm | d_{Ru} = | 11.7905 nm |
| 18 | d_{Si} = | 8.7352 nm | d_{Ru} = | 0.0000 nm |
| 19 | d_{Si} = | 0.0104 nm | d_{Ru} = | 10.9638 nm |
| 20 | d_{Si} = | 5.8251 nm | d_{Ru} = | 10.8651 nm |
| 21 | d_{Si} = | 10.1334 nm | d_{Ru} = | 10.2689 nm |
| 22 | d_{Si} = | 4.7854 nm | d_{Ru} = | 10.9044 nm |
| 23 | d_{Si} = | 11.1279 nm | d_{Ru} = | 0.0000 nm |
| 24 | d_{Si} = | 13.9900 nm | d_{Ru} = | 0.0000 nm |
| 25 | d_{Si} = | 13.4481 nm | d_{Ru} = | 0.0000 nm |
| 26 | d_{Si} = | 13.9864 nm | d_{Ru} = | 6.4612 nm |
| 27 | d_{Si} = | 10.3630 nm | d_{Ru} = | 0.7886 nm |
| 28 | d_{Si} = | 13.2990 nm | d_{Ru} = | 0.0000 nm |
| 29 | d_{Si} = | 13.0715 nm | d_{Ru} = | 0.0000 nm |
| 30 | d_{Si} = | 13.1670 nm | d_{Ru} = | 7.2923 nm |
| 31 | d_{Si} = | 14.0000 nm | d_{Ru} = | 0.0350 nm |
| 32 | d_{Si} = | 0.0455 nm | d_{Ru} = | 0.0508 nm |
| 33 | d_{Si} = | 0.0000 nm | d_{Ru} = | 0.0052 nm |
| 34 | d_{Si} = | 9.0992 nm | d_{Ru} = | 5.3858 nm |
| 35 | d_{Si} = | 9.1359 nm | d_{Ru} = | 9.1692 nm |
| 36 | d_{Si} = | 9.0522 nm | d_{Ru} = | 6.6343 nm |
| 37 | d_{Si} = | 9.4914 nm | d_{Ru} = | 6.8441 nm |
| 38 | d_{Si} = | 9.7028 nm | d_{Ru} = | 5.9849 nm |
| 39 | d_{Si} = | 10.0724 nm | d_{Ru} = | 5.4631 nm |
| 40 | d_{Si} = | 10.2388 nm | d_{Ru} = | 5.2962 nm |
| 41 | d_{Si} = | 10.3055 nm | d_{Ru} = | 5.2011 nm |
| 42 | d_{Si} = | 10.3321 nm | d_{Ru} = | 5.1586 nm |
| 43 | d_{Si} = | 10.3539 nm | d_{Ru} = | 5.1052 nm |
| 44 | d_{Si} = | 10.3842 nm | d_{Ru} = | 5.0677 nm |
| 45 | d_{Si} = | 10.4049 nm | d_{Ru} = | 5.0421 nm |
| 46 | d_{Si} = | 10.4114 nm | d_{Ru} = | 5.0427 nm |
| 47 | d_{Si} = | 10.3725 nm | d_{Ru} = | 5.1956 nm |
| 48 | d_{Si} = | 10.1710 nm | d_{Ru} = | 5.6085 nm |
| 49 | d_{Si} = | 9.9845 nm | d_{Ru} = | 5.8591 nm |
| 50 | d_{Si} = | 10.0288 nm | d_{Ru} = | 5.1012 nm |

TABLE 3
(MoSi; 25° angle of incidence; rₛ = 0.7; rₚ minimal
The silicon layer of layer 1 is located directly on the substrate.
The molybdenum layer of layer 50 forms the incidence surface
for the EUV used radiation.)

| | | | | |
|---|---|---|---|---|
| 1 | d_{Si} = | 7.7236 nm | d_{Mo} = | 4.1247 nm |
| 2 | d_{Si} = | 3.7727 nm | d_{Mo} = | 3.9637 nm |
| 3 | d_{Si} = | 3.8103 nm | d_{Mo} = | 3.9256 nm |
| 4 | d_{Si} = | 3.8385 nm | d_{Mo} = | 3.8985 nm |
| 5 | d_{Si} = | 3.8613 nm | d_{Mo} = | 3.8772 nm |
| 6 | d_{Si} = | 3.8799 nm | d_{Mo} = | 3.8583 nm |
| 7 | d_{Si} = | 3.8964 nm | d_{Mo} = | 3.8414 nm |
| 8 | d_{Si} = | 3.9109 nm | d_{Mo} = | 3.8256 nm |
| 9 | d_{Si} = | 3.9239 nm | d_{Mo} = | 3.8104 nm |
| 10 | d_{Si} = | 3.9358 nm | d_{Mo} = | 3.7956 nm |
| 11 | d_{Si} = | 3.9469 nm | d_{Mo} = | 3.7812 nm |
| 12 | d_{Si} = | 3.9572 nm | d_{Mo} = | 3.7669 nm |
| 13 | d_{Si} = | 3.9667 nm | d_{Mo} = | 3.7531 nm |
| 14 | d_{Si} = | 3.9749 nm | d_{Mo} = | 3.7412 nm |
| 15 | d_{Si} = | 3.9796 nm | d_{Mo} = | 3.7352 nm |
| 16 | d_{Si} = | 3.9756 nm | d_{Mo} = | 3.7421 nm |
| 17 | d_{Si} = | 3.9559 nm | d_{Mo} = | 3.7678 nm |
| 18 | d_{Si} = | 3.9223 nm | d_{Mo} = | 3.7969 nm |
| 19 | d_{Si} = | 3.8955 nm | d_{Mo} = | 3.8291 nm |
| 20 | d_{Si} = | 3.8322 nm | d_{Mo} = | 3.9131 nm |
| 21 | d_{Si} = | 3.7738 nm | d_{Mo} = | 3.9415 nm |
| 22 | d_{Si} = | 3.7078 nm | d_{Mo} = | 4.0771 nm |
| 23 | d_{Si} = | 3.5857 nm | d_{Mo} = | 4.0850 nm |
| 24 | d_{Si} = | 3.7453 nm | d_{Mo} = | 3.7996 nm |
| 25 | d_{Si} = | 3.8214 nm | d_{Mo} = | 4.0151 nm |
| 26 | d_{Si} = | 3.6689 nm | d_{Mo} = | 3.8402 nm |
| 27 | d_{Si} = | 3.8079 nm | d_{Mo} = | 4.0464 nm |
| 28 | d_{Si} = | 3.4973 nm | d_{Mo} = | 4.2351 nm |
| 29 | d_{Si} = | 3.4044 nm | d_{Mo} = | 4.3481 nm |
| 30 | d_{Si} = | 3.1417 nm | d_{Mo} = | 4.7698 nm |
| 31 | d_{Si} = | 3.2269 nm | d_{Mo} = | 4.2264 nm |
| 32 | d_{Si} = | 3.0257 nm | d_{Mo} = | 5.1157 nm |
| 33 | d_{Si} = | 2.9847 nm | d_{Mo} = | 4.3411 nm |
| 34 | d_{Si} = | 3.2408 nm | d_{Mo} = | 4.7565 nm |
| 35 | d_{Si} = | 2.9068 nm | d_{Mo} = | 4.6206 nm |
| 36 | d_{Si} = | 3.2913 nm | d_{Mo} = | 4.2183 nm |
| 37 | d_{Si} = | 3.2794 nm | d_{Mo} = | 4.9177 nm |
| 38 | d_{Si} = | 2.8443 nm | d_{Mo} = | 4.1465 nm |
| 39 | d_{Si} = | 3.9148 nm | d_{Mo} = | 4.0578 nm |
| 40 | d_{Si} = | 3.1493 nm | d_{Mo} = | 4.7295 nm |
| 41 | d_{Si} = | 2.9040 nm | d_{Mo} = | 4.8262 nm |
| 42 | d_{Si} = | 3.2651 nm | d_{Mo} = | 4.1901 nm |
| 43 | d_{Si} = | 3.4998 nm | d_{Mo} = | 4.1952 nm |
| 44 | d_{Si} = | 3.6395 nm | d_{Mo} = | 3.8621 nm |
| 45 | d_{Si} = | 3.9863 nm | d_{Mo} = | 3.5529 nm |
| 46 | d_{Si} = | 4.2105 nm | d_{Mo} = | 3.3495 nm |
| 47 | d_{Si} = | 4.4049 nm | d_{Mo} = | 3.1676 nm |
| 48 | d_{Si} = | 4.5380 nm | d_{Mo} = | 3.0782 nm |
| 49 | d_{Si} = | 4.5974 nm | d_{Mo} = | 3.0348 nm |
| 50 | d_{Si} = | 4.6360 nm | d_{Mo} = | 2.7202 nm |

TABLE 4
(MoSi; 25° angle of incidence; rₛ = 0.7; rₚ maximal
The silicon layer of layer 1 is located directly on the substrate.
The molybdenum layer of layer 50 forms the incidence surface
for the EUV used radiation.)

| | | | | |
|---|---|---|---|---|
| 1 | d_{Si} = | 7.7236 nm | d_{Mo} = | 4.1079 nm |
| 2 | d_{Si} = | 3.7634 nm | d_{Mo} = | 4.0723 nm |
| 3 | d_{Si} = | 3.7981 nm | d_{Mo} = | 4.0300 nm |
| 4 | d_{Si} = | 3.8289 nm | d_{Mo} = | 3.9941 nm |
| 5 | d_{Si} = | 3.8583 nm | d_{Mo} = | 3.9596 nm |
| 6 | d_{Si} = | 3.8868 nm | d_{Mo} = | 3.9262 nm |
| 7 | d_{Si} = | 3.9146 nm | d_{Mo} = | 3.8937 nm |
| 8 | d_{Si} = | 3.9418 nm | d_{Mo} = | 3.8612 nm |
| 9 | d_{Si} = | 3.9695 nm | d_{Mo} = | 3.8301 nm |
| 10 | d_{Si} = | 3.9949 nm | d_{Mo} = | 3.8004 nm |
| 11 | d_{Si} = | 4.0206 nm | d_{Mo} = | 3.7699 nm |
| 12 | d_{Si} = | 4.0475 nm | d_{Mo} = | 3.7368 nm |
| 13 | d_{Si} = | 4.0796 nm | d_{Mo} = | 3.6934 nm |
| 14 | d_{Si} = | 4.1263 nm | d_{Mo} = | 3.6282 nm |
| 15 | d_{Si} = | 4.1977 nm | d_{Mo} = | 3.5317 nm |
| 16 | d_{Si} = | 4.2988 nm | d_{Mo} = | 3.4037 nm |
| 17 | d_{Si} = | 4.4256 nm | d_{Mo} = | 3.2523 nm |
| 18 | d_{Si} = | 4.5682 nm | d_{Mo} = | 3.0900 nm |
| 19 | d_{Si} = | 4.7158 nm | d_{Mo} = | 2.9279 nm |
| 20 | d_{Si} = | 4.8592 nm | d_{Mo} = | 2.7741 nm |
| 21 | d_{Si} = | 4.9929 nm | d_{Mo} = | 2.6332 nm |
| 22 | d_{Si} = | 5.1140 nm | d_{Mo} = | 2.5072 nm |
| 23 | d_{Si} = | 5.2216 nm | d_{Mo} = | 2.3959 nm |
| 24 | d_{Si} = | 5.3162 nm | d_{Mo} = | 2.2988 nm |
| 25 | d_{Si} = | 5.3987 nm | d_{Mo} = | 2.2143 nm |
| 26 | d_{Si} = | 5.4705 nm | d_{Mo} = | 2.1410 nm |
| 27 | d_{Si} = | 5.5327 nm | d_{Mo} = | 2.0777 nm |
| 28 | d_{Si} = | 5.5866 nm | d_{Mo} = | 2.0230 nm |
| 29 | d_{Si} = | 5.6333 nm | d_{Mo} = | 1.9757 nm |
| 30 | d_{Si} = | 5.6738 nm | d_{Mo} = | 1.9348 nm |
| 31 | d_{Si} = | 5.7090 nm | d_{Mo} = | 1.8994 nm |
| 32 | d_{Si} = | 5.7396 nm | d_{Mo} = | 1.8687 nm |
| 33 | d_{Si} = | 5.7662 nm | d_{Mo} = | 1.8423 nm |
| 34 | d_{Si} = | 5.7893 nm | d_{Mo} = | 1.8196 nm |
| 35 | d_{Si} = | 5.8094 nm | d_{Mo} = | 1.8002 nm |
| 36 | d_{Si} = | 5.8266 nm | d_{Mo} = | 1.7837 nm |
| 37 | d_{Si} = | 5.8414 nm | d_{Mo} = | 1.7701 nm |
| 38 | d_{Si} = | 5.8540 nm | d_{Mo} = | 1.7589 nm |
| 39 | d_{Si} = | 5.8646 nm | d_{Mo} = | 1.7502 nm |
| 40 | d_{Si} = | 5.8737 nm | d_{Mo} = | 1.7438 nm |
| 41 | d_{Si} = | 5.8815 nm | d_{Mo} = | 1.7397 nm |
| 42 | d_{Si} = | 5.8885 nm | d_{Mo} = | 1.7380 nm |
| 43 | d_{Si} = | 5.8946 nm | d_{Mo} = | 1.7395 nm |
| 44 | d_{Si} = | 5.8983 nm | d_{Mo} = | 1.7449 nm |
| 45 | d_{Si} = | 5.9017 nm | d_{Mo} = | 1.7537 nm |
| 46 | d_{Si} = | 5.9027 nm | d_{Mo} = | 1.7675 nm |
| 47 | d_{Si} = | 5.8995 nm | d_{Mo} = | 1.7883 nm |
| 48 | d_{Si} = | 5.8868 nm | d_{Mo} = | 1.8176 nm |
| 49 | d_{Si} = | 5.8528 nm | d_{Mo} = | 1.9389 nm |
| 50 | d_{Si} = | 5.7606 nm | d_{Mo} = | 2.5331 nm |

The concept according to the invention of exchanging at least one reflective component located in the optical beam path for a component that corresponds in respect of its surface geometry but differs in respect of the reflection layer system present, for the purposes of changing the mode of operation between “polarized” and “unpolarized”, can be realized for different components of the optical system or of the illumination device as a matter of principle.

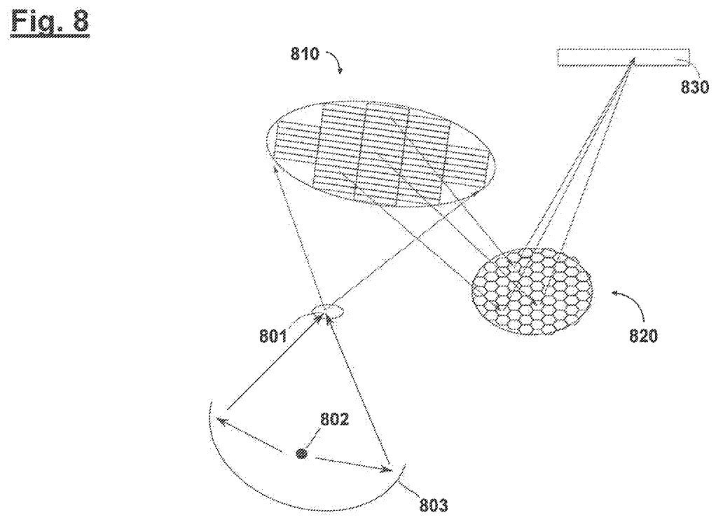

FIG. 8 initially shows a schematic and much simplified representation of a possible basic structure of an illumination device of a microlithographic projection exposure apparatus designed for operation in the EUV wavelength range. In this case, the EUV radiation produced by an EUV radiation source 802 (e.g., a plasma source) reaches a field facet mirror 810 with a multiplicity of independently adjustable field facets (e.g., for setting different illumination settings) via an intermediate focus 801 following the reflection at a collector mirror 803. From the field facet mirror 810, the EUV radiation is incident on a pupil facet mirror 820 and, from the latter, on a reticle 830 which is situated in the object plane of the projection lens (not depicted in FIG. 8) disposed downstream in the optical beam path.

The invention is not restricted to the structure of the illumination device as illustrated in FIG. 8. Thus, one or more additional optical elements, for example in the form of one or more deflection mirrors, can also be arranged in the beam path in further embodiments.

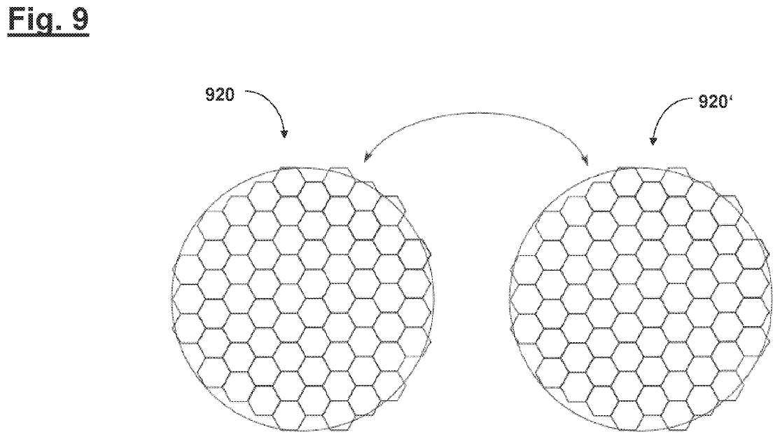

Possible implementations of the “component exchange” according to the invention are explained below with reference to the merely schematic illustrations of FIGS. 9-12.

With reference to FIG. 9, initially, the pupil facet mirror (denoted by “920” in FIG. 9) can be exchanged overall for another pupil facet mirror 920′ (which according to the concept according to the invention differs from the pupil facet mirror 920 not in terms of its surface geometry but in terms of its spectral reflection profiles or reflection layer systems) for the purposes of implementing the component exchange according to the invention for the purpose of changing the mode of operation between “polarized” and “unpolarized”. This implementation is advantageous inasmuch as only a single component has to be exchanged.

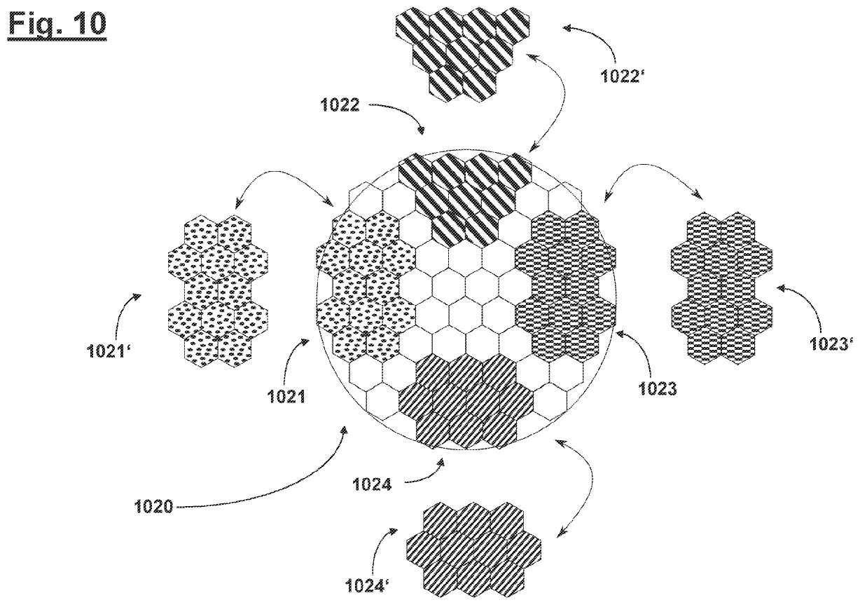

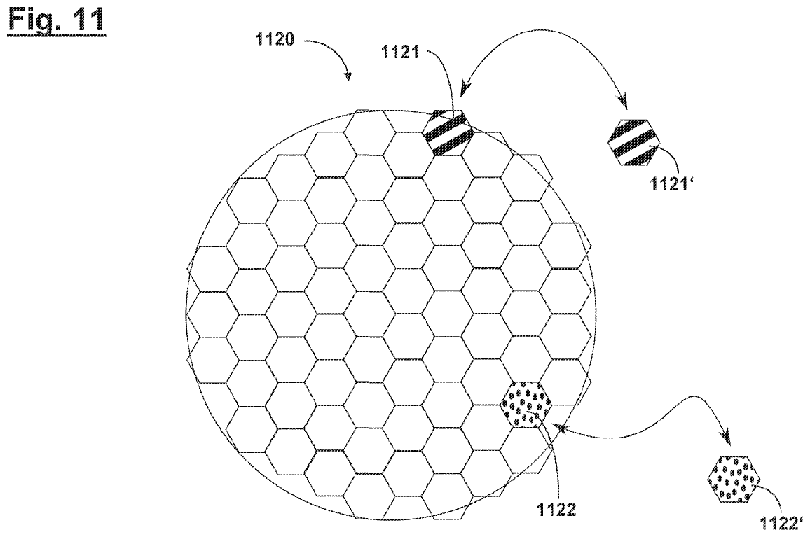

In a further embodiment, illustrated in FIG. 10, it is also possible to exchange individual segments (denoted by “1021” to “1024” in FIG. 10) of a pupil facet mirror 1020 for other segments (denoted “1021′” to “1024′” in FIG. 10), with the respective segments in turn comprising a plurality of pupil facets. This embodiment is advantageous inasmuch as the number of elements to be realized as exchangeable is comparatively small. As indicated in FIG. 11, a single pupil facet (e.g., “1121” or “1122”) of a pupil facet mirror 1120 can also be exchanged for another pupil facet 1121′ or 1122′ (which in conformity with the concept according to the invention is designed with the same surface geometry but different spectral reflection profiles or reflection layer systems) in a further embodiment.

To the extent that reference is made to a pupil facet mirror in the embodiments described above, there can be an analogous realization for the field facet mirror as well.

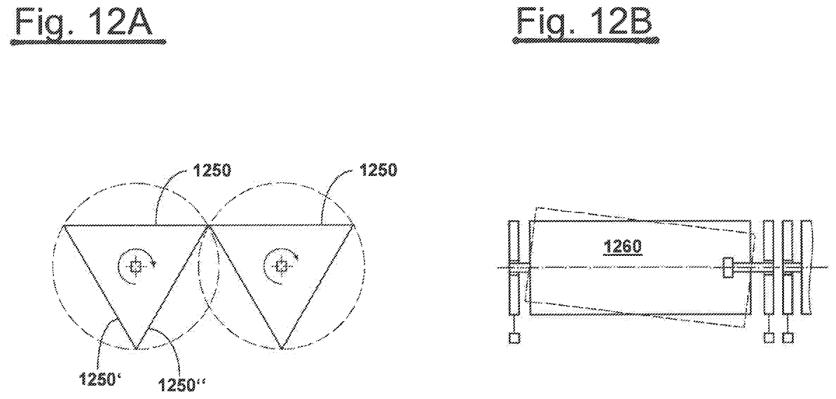

FIGS. 12A-12B show, purely in a schematic representation, a further implementation option for the component interchange according to the invention. In this case, up to three field facets 1250, 1250′, 1250″ can be arranged on an exchange apparatus 1260 designed as a roller, in an arrangement known per se from DE 10 2018 207 410 A1, with rotating the roller allowing a “switch” between said field facets 1250, 1250′, 1250″. By tilting the axis of rotation, the respective selected field facet 1250, 1250′ or 1250″ can be tilted so that a desired pupil facet of the pupil facet mirror is illuminated. In this case, according to the invention, the three field facets 1250, 1250′, 1250″ situated on a common roller are provided with different reflection layer systems.

In a further variant, the reflection layer systems can be attached to the collector mirror 803, reference having made to FIG. 8 again. Advantageous embodiments of a collector mirror for simplifying the highly accurate interchange thereof, are known from DE 10 2013 200 368 A1.

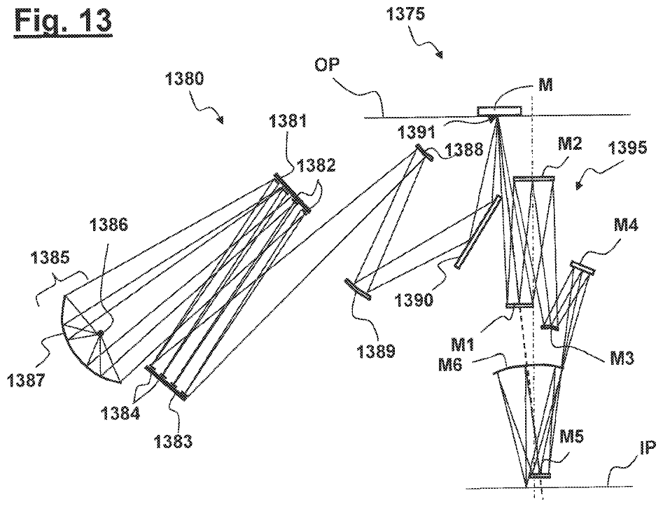

FIG. 13 shows a schematic illustration of an exemplary projection exposure apparatus which is designed for operation in the EUV and in which the present invention can be realized. According to FIG. 13, an illumination device 1380 in a projection exposure apparatus 1375 designed for EUV comprises a field facet mirror 1381 (with facets 1382) and a pupil facet mirror 1383 (with facets 1384). The light from a light source unit 1385 comprising a plasma light source 1386 and a collector mirror 1387 is directed at the field facet mirror 1381. A first telescope mirror 1388 and a second telescope mirror 1389 are arranged in the light path downstream of the pupil facet mirror 1383. A deflection mirror 1390 is arranged downstream in the light path, said deflection mirror steering the radiation that is incident thereon to an object field 1391 in the object plane OP of a projection lens 1395 comprising six mirrors M1-M6. A reflective structure-bearing mask M, which is imaged into an image plane IP with the aid of the projection lens 1395 (comprising six mirrors M1-M6), is arranged at the location of the object field 1391.

Even though the invention has been described on the basis of specific embodiments, numerous variations and alternative embodiments will be apparent to a person skilled in the art, for example through combination and/or exchange of features of individual embodiments. Accordingly, it will be apparent to a person skilled in the art that such variations and alternative embodiments are also encompassed by the present invention, and the scope of the invention is restricted only within the scope of the appended patent claims and the equivalents thereof.

What is claimed is:

1. Optical component group, comprising:
a first reflective component having a first reflection layer system; and
a second reflective component having a second reflection layer system;
wherein the first reflective component and the second reflective component have respective optically effective surfaces that correspond mutually in geometry;
wherein spectral reflection profiles (r₁ₛ(λ), r₁ₚ(λ)) of the first reflection layer system differ from corresponding spectral reflection profiles (r₂ₛ(λ), r₂ₚ(λ)) of the second reflection layer system for a given wavelength interval and a given angle of incidence of incident electromagnetic radiation, the spectral reflection profiles of the first reflection layer system describing respective wavelength dependences of the reflectivity for s-polarized radiation and for p-polarized radiation; and
wherein a wavelength λ₀ exists as mean wavelength in a given wavelength interval [(λ₀−Δλ₀/2), (λ₀+Δλ₀/2)] of width Δλ₀ such that the first reflection layer system satisfies the following conditions:
$$( {λ}_{0} - {Δλ}_{0} / 2 ) \geq {λ}_{1 sl} , ( {λ}_{0} + {Δλ}_{0} / 2 ) \leq {λ}_{1 sr} \\ and \\ ( {λ}_{0} - {Δλ}_{0} / 2 ) \leq {λ}_{1 pl} or ( {λ}_{0} + {Δλ}_{0} / 2 ) \geq {λ}_{1 pr} ,$$
where, in the reflection profiles (r₁ₛ(λ), r₁ₚ(λ)) of the first reflection layer system, λ₁ₛ, and λ₁ₚₗ denote the shortest wavelengths and λ₁ₛᵣ and λ₁ₚᵣ denote the longest wavelengths for which in each case s- and p-polarized radiation, respectively, is reflected with a reflectivity of at least 50% of a maximum reflectivity.

2. Optical component group according to claim 1, wherein a wavelength λ₀ exists as mean wavelength in a given wavelength interval [(λ₀−Δλ₀/2), (λ₀+λ₀/2)] of width Δλ such that the second reflection layer system satisfies the following conditions:
$$( {λ}_{0} - {Δλ}_{0} / 2 ) \geq {λ}_{2 sl} , ( {λ}_{0} + {Δλ}_{0} / 2 ) \leq {λ}_{2 sr} \\ and \\ ( {λ}_{0} - {Δλ}_{0} / 2 ) \geq {λ}_{2 pl} , ( {λ}_{0} + {Δλ}_{0} / 2 ) \leq {λ}_{2 pr}$$
where, in the reflection profiles (r₂ₛ(λ), r₂ₚ(λ)) of the second reflection layer system, λ₂ₛₗ and λ₂ₚₗ denote the shortest wavelengths and λ₂ₛᵣ and λ₂ₚᵣ denote the longest wavelengths for which in each case s- and p-polarized radiation, respectively, is reflected with a reflectivity of at least 50% of a maximum reflectivity.

3. Optical component group according to claim 1, wherein a wavelength λ₀ exists as mean wavelength in a given wavelength interval [(λ₀−Δλ₀/2), (λ₀+λ₀/2)] of width Δλ such that the second reflection layer system satisfies the following conditions:
$$( {λ}_{0} - {Δλ}_{0} / 2 ) \geq {λ}_{2 sl} , ( {λ}_{0} + {Δλ}_{0} / 2 ) \leq {λ}_{2 sr} \\ and \\ ( {λ}_{0} - {Δλ}_{0} / 2 ) \geq {λ}_{2 pl} , ( {λ}_{0} + {Δλ}_{0} / 2 ) \leq {λ}_{2 pr}$$
where, in the reflection profiles (r₂ₛ(λ), r₂ₚ(λ)) of the second reflection layer system, λ₂ₛₗ and λ₂ₚₗ denote the shortest wavelengths and λ₂ₛᵣ and λ₂ₚᵣ denote the longest wavelengths for which in each case s- and p-polarized radiation, respectively, is reflected with a reflectivity of at least 50% of the maximum reflectivity.

4. Optical component group according to claim 1, wherein a wavelength λ₀ exists as mean wavelength in a given wavelength interval [(λ₀−Δλ₀/2), (λ₀+λ₀/2)] of width Δλ such that the first reflection layer system satisfies the following conditions:
$$( {λ}_{0} - {Δλ}_{0} / 2 ) \geq {λ}_{1 sl} , ( {λ}_{0} + {Δλ}_{0} / 2 ) \leq {λ}_{1 sr} \\ and \\ ( {λ}_{0} - {Δλ}_{0} / 2 ) \leq {λ}_{1 pl} or ( {λ}_{0} + {Δλ}_{0} / 2 ) \geq {λ}_{1 pr} ,$$
and the second reflection layer system satisfies the following conditions:
$$( {λ}_{0} - {Δλ}_{0} / 2 ) \geq {λ}_{2 sl} , ( {λ}_{0} + {Δλ}_{0} / 2 ) \leq {λ}_{2 sr} \\ and \\ ( {λ}_{0} - {Δλ}_{0} / 2 ) \geq {λ}_{2 pl} , ( {λ}_{0} + {Δλ}_{0} / 2 ) \leq {λ}_{2 pr}$$
where, in the reflection profiles (r₁ₛ(λ), r₁ₚ(λ)) of the first reflection layer system and (r₂ₛ(λ), r₂ₚ(λ)) of the second reflection layer system, λ₁ₛₗ, λ₁ₚₗ, λ₂ₛₗ and λ₂ₚₗ denote the respective shortest wavelengths and λ₁ₛᵣ, λ₁ₚᵣ, λ₂ₛᵣ and λ₂ₚᵣ denote the respective longest wavelengths for which in each case s- and p-polarized radiation, respectively, is reflected with a reflectivity of at least 50% of a maximum reflectivity.

5. Optical component group according to claim 1, wherein a degree of polarization for the first reflection layer system, defined as a ratio of the reflectivities for s- and p-polarized radiation integrated over the wavelength interval [(λ₀−Δλ₀/2), (λ₀+λ₀/2)], is greater than a degree of polarization for the second reflection layer system by a factor of at least 1.5.

6. Optical component group according to claim 1, wherein, for s-polarized radiation in an interval [symbol] =[(λ₁ₛᵣ−λ₁ₛₗ)+(λ₂ₛᵣ−λ₂ₛₗ)]/2, the second reflective component has a reflectivity of at least 50% of the maximum transmissivity of an extreme ultraviolet illumination device comprising the optical component, where Δλ₀ lies between [symbol] and [symbol] .

7. Optical component group according to claim 1, wherein both the first reflective component and the second reflective component comprise at least one mirror facet of a facet mirror.

8. Optical component group according to claim 7, wherein both the first reflective component and the second reflective component comprise at least one mirror facet of a pupil facet mirror or of a field facet mirror.

9. Optical component group according to claim 1, wherein both the first reflective component and the second reflective component are facet mirrors.

10. Optical component group according to claim 9, wherein the facet mirrors are pupil facet mirrors each having a plurality of pupil facets or field facet mirrors each having a plurality of field facets.

11. Optical component group according to claim 1, wherein both the first reflective component and the second reflective component are collector mirrors.

12. Optical component group according to claim 1, wherein both the first reflective component and the second reflective component comprise a micromirror of a specular reflector.

13. Optical component group according to claim 1, wherein the first reflective component and the second reflective component are configured for an operating wavelength of less than 30 nm.

14. Optical component group according to claim 13, wherein the first reflective component and the second reflective component are configured for an operating wavelength of less than 15 nm.
